(19) United States
(12) Patent Application Publication
(10) Pub. No.: US 2015/0054162 A1
(43) Pub. Date: Feb. 26, 2015

(54) METHOD OF MANUFACTURING CHIP PACKAGE SUBSTRATE AND METHOD OF MANUFACTURING CHIP PACKAGE

(71) Applicant: LG INNOTEK CO., LTD., Seoul (KR)

(72) Inventor: Hong Il Kim, Seoul (KR)

(21) Appl. No.: 14/394,583

(22) PCT Filed: Apr. 12, 2013
(86) PCT No.: PCT/KR2013/003076

§ 371 Date: Oct. 15, 2014

(30) Foreign Application Priority Data
Apr. 16, 2012 (KR) 10-2012-0039251

(51) Int. Cl. H01L 23/00

(52) U.S. Cl. CPC H01L 24/05; H01L 24/29; H01L 2224/04042; H01L 2224/05023; H01L 2224/05144; H01L 2224/05155; H01L 2924/01015; H01L 2924/01005; H01L 2924/14; H01L 2224/05083; H01L 2224/05025
USPC 257/766

(57) ABSTRACT

A chip package substrate includes a base substrate including via holes. A circuit pattern layer is formed in an area of the base substrate corresponding to the via holes, and a first plated layer formed on the other surface opposite to one surface of the circuit pattern layer in contact with the via holes.

### TECHNICAL FIELD

The present invention relates to the technical field of a chip package, more specifically, a technology of manufacturing a chip package substrate.

### BACKGROUND ART

The technologies relating to a semiconductor or an optical device package have been steadily developed to meet the requirements for high densification, miniaturization, and high performance. However, because the technologies have relatively fallen behind technologies for manufacturing a semiconductor, attempts have been recently made to settle the requirements for high performance, miniaturization and high densification by the development of technologies relating to packages.

In connection with semiconductor/optical device packages, a silicon chip or an LED (light emitting diode) chip, a smart IC chip and the like are bonded onto a substrate using a wire bonding method or an LOC (lead on chip) bonding method.

FIG. 1 illustrates a cross-sectional view of a general smart IC chip package.

Referring to FIG. 1, the general smart IC chip package includes: an insulating layer 10; a circuit pattern layer 20 formed on one surface of the insulating layer; and an IC chip 30.

The IC chip 30 is electrically connected to the circuit pattern layer 20 using a wire 40. The IC chip 30 and the wire 40 are molded by a molding part 50 composed of epoxy resin and the like. As illustrated in FIG. 1, the molding part 50 is formed on the insulating layer 10. Here, one surface of the circuit pattern layer 20 to which a molding resin is applied becomes a bonding area. Another surface of the circuit pattern layer 20 becomes a contact area. Also, a plated layer 60 is formed in the contact area of the circuit pattern layer 30.

The plated layer 60 is formed by an Ni-Au plating method. Ni and Au have been used as a protective barrier metal against corrosion or other chemical attacks as well as finishing materials for securing functionality in semiconductor and chip carrier business circles. Thus, the plated layer 60 formed in the contact area of the circuit pattern layer is just formed on the circuit pattern layer 30, and includes an Ni layer 62 composed of Ni, and an Au layer 64 formed on the Ni layer. The plated layer 60 is formed by the Ni—Au plating method.

However, existing electrolytic Ni—Au plating has a quality characteristic which requires hardness, but as the price of gold increases, a cost for the plating accounts for more than 30% of a production cost of the existing smart IC chip package.

### DISCLOSURE OF INVENTION

### Technical Problem

The present invention has been made keeping in mind the above problems. An aspect of the present invention provides a smart IC chip package and a method of manufacturing the same, which enables a production cost to be reduced.

### Solution to Problem

According to an aspect of the present invention, there is provided a chip package substrate including: an insulating layer on which via holes are formed; a circuit pattern layer formed on one surface of the insulating layer; and a plated layer formed on one surface of the circuit pattern layer, wherein the plated layer includes: an Ni layer formed on the one surface of the circuit pattern layer; an alloy layer formed on the nickel layer; and an Au layer formed on the alloy layer.

The alloy layer may be formed of an alloy of three elements of Ni—P—B.

The alloy layer may have a thickness of 0.5±0.2 μm, and the Au layer may have a thickness of 0.05±0.02 μm.

The insulating layer may be formed of polyimide, polyethylene naphtalate or polyethyleneterephthalate.

The chip package substrate may further include a lower adhesive layer which is located between the insulating layer and the circuit pattern layer, and bonds the circuit pattern layer to the insulating layer.

The lower adhesive layer may be composed of an adhesive or a bonding sheet.

The chip package substrate may further include another plated layer formed on another surface of the circuit pattern layer.

The one surface of the circuit pattern layer may be a contact surface of a chip package, and the another surface of the circuit pattern layer may be a bonding surface of the chip package.

The one surface of the circuit pattern layer may be a surface opposed to a surface of the circuit pattern layer adjacent to the insulating layer.

Also, according to another aspect of the present invention, there is provided a method of manufacturing a chip package substrate, the method including: forming via holes on an insulating layer; forming a circuit pattern layer on one surface of the insulating layer; and forming a plated layer on one surface of the circuit pattern layer, wherein the forming of the plated layer includes: forming an Ni layer on the one surface of the circuit pattern layer; forming an alloy layer on the Ni layer; and forming an Au layer on the alloy layer.

The method of manufacturing the chip package substrate may further include forming a lower adhesive layer on one surface of the insulating layer before the forming of the circuit pattern layer.

The forming of the circuit pattern layer may include forming a metal layer on the lower adhesive layer; and forming a circuit pattern by etching the metal layer.

A material of the metal layer may be Cu.

The method of manufacturing the chip package substrate may further include forming another plated layer on another surface of the circuit pattern layer.

### Advantageous Effects of Invention

According to the present invention, in the chip package substrate, because the alloy layer of three elements of Ni—P—B is added between the Ni layer and the Au layer of the plated layer formed on the circuit pattern layer in the smart IC package, hardness is increased up to two times and a plated thickness of the Au layer is reduced. Thus, in the plated layer according to the present invention, the thickness of the Au layer having a high material cost is reduced. Thus, it is advantageous that the amount used of Au is reduced, thereby enabling the total production cost of a product to be reduced.

Furthermore, according to the present invention, it is advantageous that because adhesive strength between an insulation film and a molding resin at the time of manufacturing the chip package can be improved, reliability and durability of the chip package can be improved. Moreover, according to the present invention, as the chip package is manufactured using the insulation film, it can be additionally provided with the effect that the product can be getting lighter, smaller, thinner and simplified.

### BRIEF DESCRIPTION OF DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 illustrates a cross-sectional view of a general smart IC chip package.

FIG. 2 is a flow chart showing the flow of a method of manufacturing a chip package substrate according to the present invention.

FIG. 3a and FIG. 3b show exemplary process views schematically illustrating the processes of a method of manufacturing a chip package according to an exemplary embodiment of the present invention.

FIG. 4 illustrates a cross-sectional view of a chip package substrate according to another exemplary embodiment of the present invention.

FIG. 5 is a view showing a structure of a plated layer according to a preferred exemplary embodiment of the present invention.

FIG. 6 is a view showing the results of a hardness test relating to plated layers according to a conventional technology and the present invention.

### MODE FOR THE INVENTION

Exemplary embodiments according to the present invention will now be described more fully hereinafter with reference to the accompanying drawings. The exemplary embodiments of the present invention may, however, be embodied in many different forms and should not be construed as limited to the embodiments set forth herein. Rather these example embodiments are provided so that this disclosure will be thorough and complete, and will fully convey the scope of the invention to those skilled in the art. Furthermore, when it is determined that specific descriptions regarding publicly known relevant functions or configurations may unnecessarily be beside main points of the present invention, corresponding descriptions are omitted. It will be further understood that terms used herein should be interpreted as having a meaning that is consistent with their meaning in the context of this specification. With regard to the elements which perform similar functions and operations, like numbers refer to like elements throughout the specification.

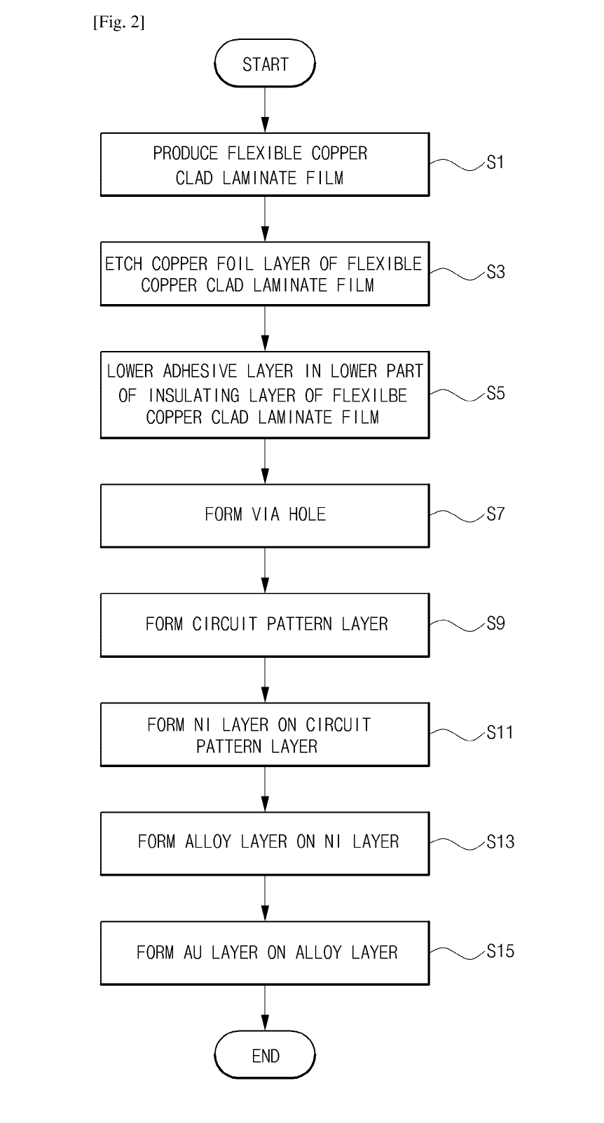

FIG. 2 is a flow chart showing the flow of a method of manufacturing a chip package substrate according to the present invention.

Referring to FIG. 2, a method of manufacturing a chip package substrate may include: producing a flexible copper clad laminate (FCCL) film composed of a structure in which an insulating layer, an adhesive layer, and a copper foil layer are sequentially laminated (S1); etching the copper foil layer of the flexible copper clad laminate film so that it is removed (S3); producing a base material by forming a lower adhesive layer in a lower part of the insulating layer (S5); forming via holes on the base material (S7); forming a circuit pattern layer in a lower part of the base material (S9); and forming a plated layer on the circuit pattern layer. The forming of the plated layer according to the present invention includes: forming an Ni layer on the circuit pattern layer (S11); forming an alloy layer on the Ni layer (S13); and forming an Au layer on the alloy layer (S15).

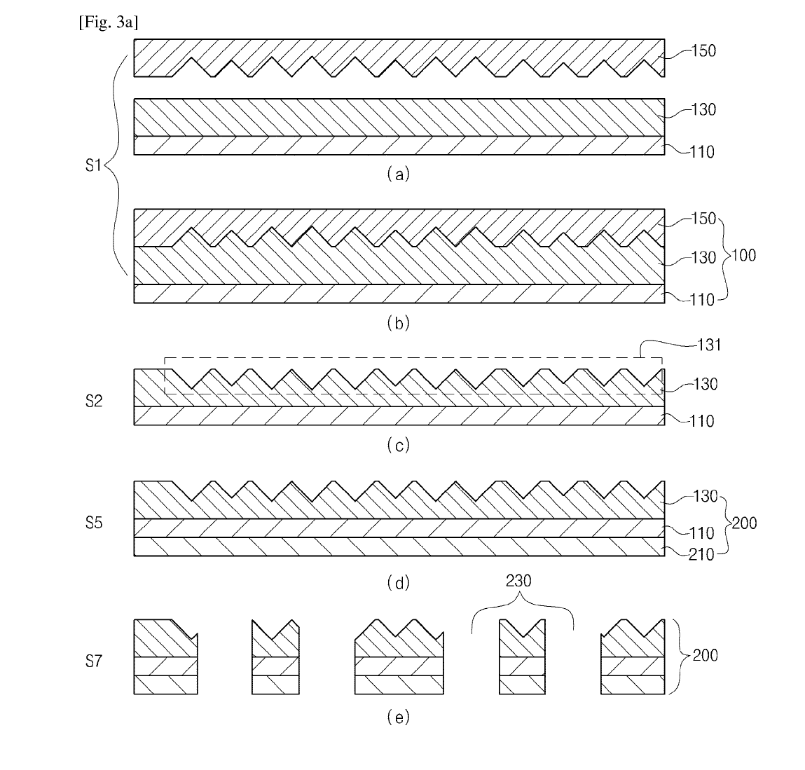

Hereinafter, the detailed explanation on each step will be described with reference to FIG. 3a and FIG. 3b.

FIG. 3a and FIG. 3b show exemplary process views schematically illustrating the processes of a method of manufacturing a chip package according to an exemplary embodiment of the present invention.

Step S1 may be concretely performed as follows.

First, an insulation film is prepared. At this time, the insulation film may be formed of a polyimide resin film material or a polyethylene naphthalate resin film material, and preferably a polyimide resin film material. However, the materials are not limited to this.

Then, the insulation film becomes an insulating layer 110. An adhesive layer 130 is formed on one surface of the insulating layer 110. At this time, with regard to a material which forms the adhesive layer 130, the adhesive layer 130 may be formed of a material including at least any one of epoxy resin, acrylic resin, and polyimide resin. In particular, the epoxy resin or the polyimide resin may be used. With intent to have flexibility, various natural rubbers, a plasticizer, a hardener, phosphorous flame retardant, and other various additives may be added to the material which forms the adhesive layer. Furthermore, the polyimide resin mainly uses thermal polyimide, but thermal curable polyimide resin may be also used. However, this is only one example. The adhesive layer of the present invention may be formed of all resins having adhesive properties which have been developed and commercialized, or can be implemented according to future technical development.

Then, a copper foil layer 150 is formed by laminating an electrolytic copper foil on the adhesive layer. Thus, a flexible copper foil laminate film 100 is manufactured. At this time, roughness formed on a surface of the electrolytic copper foil is reflected in the adhesive layer 130. Consequently, surface roughness is formed on the adhesive layer 130. At this time, the surface roughness Rz formed on the adhesive layer 130 may be adjusted by adjusting conditions such as a thickness of the electrolytic copper foil, laminating conditions (for example, temperature or pressure), and the like. The surface roughness Rz formed on the adhesive layer may be formed within a range of 3 to 10 μm, but the range is not limited to this. In a case where the roughness Rz is less than 3 μm, it would be difficult to improve adhesive strength with a molding part which will be formed later at the time of manufacturing a complete product. When the roughness Rz is more than 10 μm, it is problematic that grains which form the surface roughness are separated in a powder shape, thereby causing pollution during a manufacturing process relating a chip package.

After manufacturing the flexible copper foil laminate film, as illustrated in (C) of FIG. 3a, the copper foil layer 150 is removed by an etching process (S3). Like this, when the copper foil layer is removed, constructions composed of the insulating layer and the adhesive layer, which is formed on the insulating layer, and on which surface roughness 131 is formed, may be obtained. Thus, in the case of applying a molding resin to the insulating layer later, thanks to the surface roughness formed on the insulating layer, adhesive strength between the insulating layer and the molding resin can be improved, and reliability and durability of the chip package can be improved.

After removing the copper foil layer (S3), a lower adhesive layer 210 is formed in a lower part of the insulating layer 110 among the constructions obtained from step S3. Hereinafter, the construction in which the lower adhesive layer, the insulating layer, and the adhesive layer are sequentially laminated is defined as a base material 200.

The lower adhesive layer 210 may be formed by a method of performing a laminating process after applying an adhesive or a method of performing a laminating process after bonding a bonding sheet to a lower part of the insulating layer.

In a case where the lower adhesive layer is formed by applying an adhesive to it, like the adhesive layer in step S1, the adhesive layer may be formed of a material including at least one of epoxy resin, acrylic resin, polyimide resin. In particular, it would be preferable to use the epoxy resin or the polyimide resin. With intent to have flexibility, various natural rubbers, a plasticizer, a hardener, phosphorous flame retardant, and other various additives may be added to the material which forms the adhesive layer. Furthermore, as the polyimide resin, thermal polyimide may be mainly used, but thermal curable polyimide resin may be also used.

Then, as illustrated in (e) of FIG. 3a, one or more via holes are formed in the base material 200 (S7). The via holes may include a via hole on which a chip is mounted, a via hole for electrically connecting each layer, a thermal via hole for easily diffusing heat, and a via hole which becomes a basis for aligning each layer. At this time, as a method of forming the via holes, a punching processing method, a method of carrying out a drill process using a laser, and the like may be used. In addition to this, all methods of forming the via holes, which have been developed and commercialized, or can be implemented according to future technical development may be used.

After the via holes 230 are formed on the base material 200, a circuit pattern layer 330 is formed in a lower part of the base material 200 (S9). At this time, the formation of the circuit pattern layer may be performed as follows. As illustrated in FIG. (f) of FIG. 3b, a metal layer 310 is first formed in a lower part of the base material 200. At this time, the metal layer 310 may be formed of Cu. However, the material is not limited to this. Then, a circuit pattern layer 330 is formed by etching the metal layer 310. More specifically, after a surface of the metal layer is activated through various chemical treatments, a photo resist is then applied thereto, and exposure and development processes are carried out. After completing the development process, a necessary circuit is formed by the etching process, and the circuit pattern layer 330 is formed by peeling off the photo resist.

Subsequently, in step S11, an Ni layer 410 is formed on one surface of the circuit pattern layer 330, namely, a surface of a contact area of the circuit pattern layer 330. In step S13, an alloy layer 420 is formed on the Ni layer 410. The alloy layer 420 may be formed by plating the Ni layer with a plating solution including Ni, P and B. That is, the alloy layer 420 is composed of an alloy of three elements of Ni, P and B. Lastly, in step S15, an Au layer 430 is formed on the alloy layer 420.

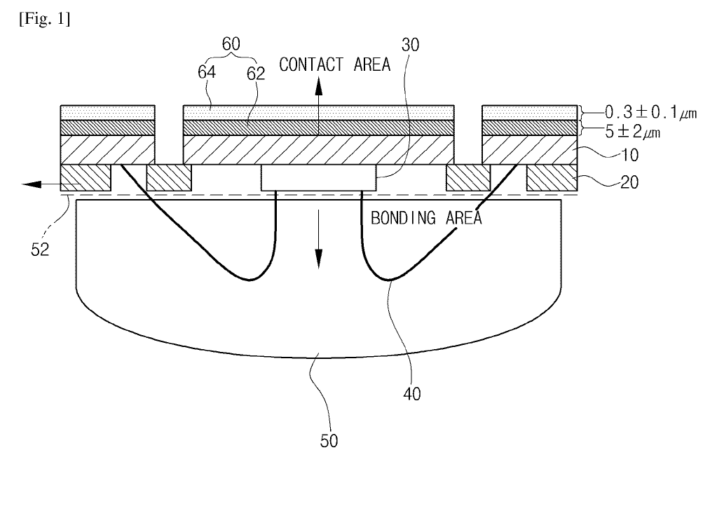

A conventional plated layer is made by forming the Au layer on the Ni layer. Referring to FIG. 1, in the conventional plated layer, the Ni layer has a thickness of 0.3±0.1 μm, and the Au layer has a thickness of 5±2 μm. The plated layer 400 according to the present invention is produced by plating the Ni layer 410 with the alloy of three elements of Ni—P—B to form the alloy layer 420, and thereafter, forming the Au layer 430.

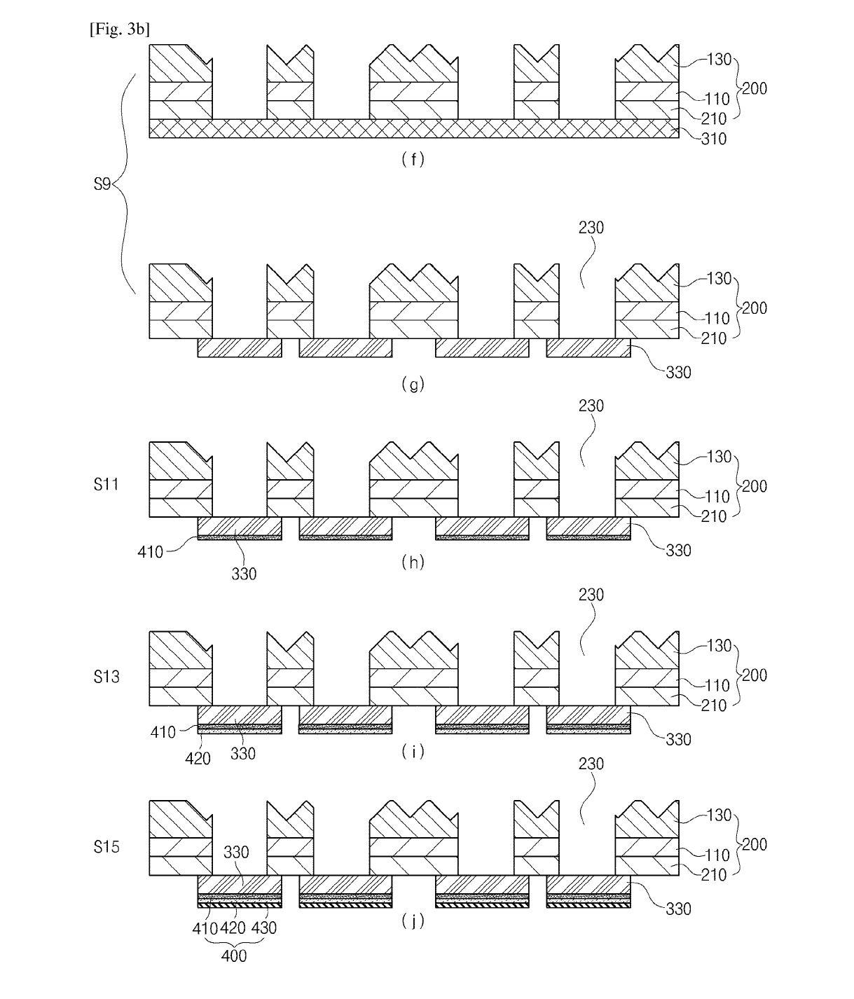

FIG. 4 illustrates a cross-sectional view of a chip package substrate according to another exemplary embodiment of the present invention.

In the exemplary embodiment as described above, it is described that the plated layer is only formed on the contact surface of the circuit pattern layer 330. However, the plated layer may be also formed on a bonding surface to which a wire for an electrical connection with a chip of the circuit pattern layer 330 is bonded. This is a matter which is obvious to those having ordinary skill in the art.

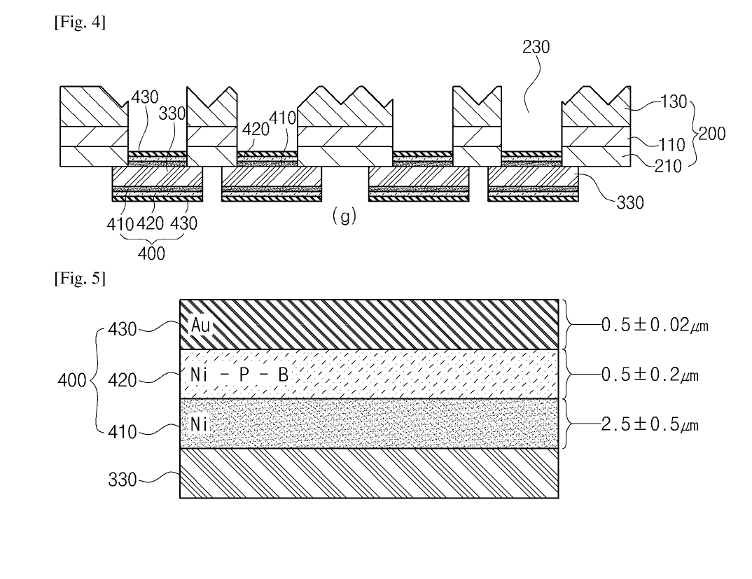

Referring to FIG. 4, the Ni layer 410 is formed on a surface of a bonding area of the circuit pattern layer 330, and the alloy layer 420 is formed on the Ni layer 410. The alloy layer 420 may be formed by plating the Ni layer 410 with the plating solution including Ni, P and B. The alloy layer 420 is composed of an alloy of three elements of Ni, P and B. Lastly, the Au layer 430 is formed on the alloy layer 420. FIG. 5 is a view showing a structure of the plated layer according to a preferred exemplary embodiment of the present invention.

Referring to FIG. 5, the plated layer 400 is formed on one surface of the circuit pattern layer 330. The plated layer 400 includes: the Ni layer 410 formed on the circuit pattern layer 330; the alloy layer 420 formed on the Ni layer 410; and the Au layer 430 formed on the alloy layer 420. The Ni layer 410 has a thickness of 2.5±0.5 μm, and the alloy layer 420 has a thickness of 0.5±0.2 μm. Furthermore, the Au layer 430 has a thickness of 0.05±0.02 μm.

The plated layer 400 according to the present invention has excellent hardness compared to the existing Ni—Au plated layer and electric resistance in a similar level to the existing plated layer. Thus, the plated layer of the existing smart IC package may be replaced by the plated layer 400 according to the present invention. In the plated layer 400 of the present invention, because the thickness of the Au layer having a high material price is reduced, the amount used of Au is reduced, thereby enabling a total production cost of the product to be reduced.

The plated layer 400 according to the present invention shows surface resistivity as shown in the following Table 1.

TABLE 1

Material of Plated Layer

| | Ni/Au | Ni/Ni—P—B/Au |
|---|---|---|
| | (Conventional Art) | (The present invention) |
| Unit [ohm/sq] | 0.00077 | 0.00077 |

As shown in Table 1 above, the plated layer according to the conventional art shows a surface resistivity of 0.00077 ohm/sq, and the plated layer according to the present invention also shows the surface resistivity of 0.00077 ohm/sq to be identical to that of the plated layer according to the conventional art. To apply the alloy layer of three elements Ni—P—B to the plated layer, the surface resistivity should be not higher than that of the existing Ni and Au plated layers. As a result of measuring their surface resistivity, it was measured as having the same level as the existing Ni and Au plating.

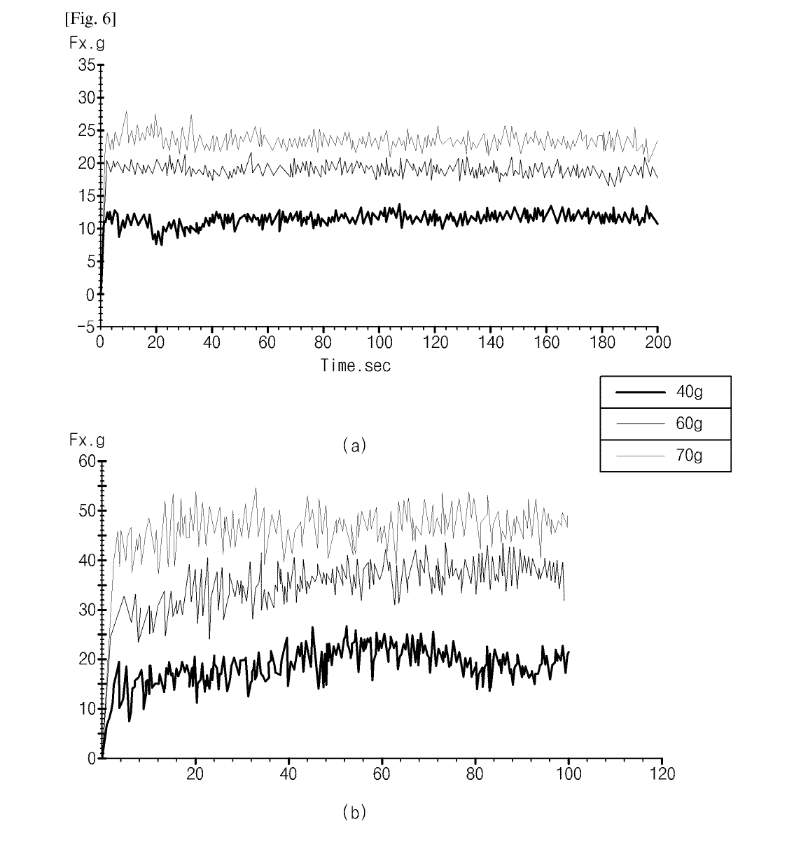

Furthermore, the plated layer according to the present invention shows the results of a scratch test as shown in FIG. 5. FIG. 6 is a view showing the results of a hardness test concerning a plated layer according to the conventional technology. In FIG. 6, (a) shows the results of a hardness test concerning the plated layer according to the conventional technology. Furthermore, (b) shows the results of a hardness test concerning the plated layer according to the present invention.

The hardness was measured using a thin film scratch tester (i.e. Multi-Scratch Test & Friction Coefficient Tester under Model No. UNMT-2M manufactured by Center for Tribology) at a velocity of 0.05 mm/sec, by giving three changes in load in a range of 40 g, 60 g, and 70 g. As illustrated in FIG. 5, the plated layer according to the present invention shows the hardness which is increased up to about two times compared to the plated layer according to the conventional technology. For example, with regard to the hardness measured in the load of 40 g, the plated layer according to the conventional layer shows a hardness value of about 12˜13, and the plated layer according to the present invention shows a hardness value of about 20˜24.

Like this, in the present invention, as the alloy layer of three elements of Ni—P—B is added between the Ni layer and the Au layer of the plated layer formed on the circuit pattern layer in the Smart IC package, the hardness is increased up to two times and a plated thickness of the Au layer is reduced.

Furthermore, the chip package substrate forms surface roughness on one surface of the insulating layer coated with the molding resin and has improved roughness. Thus, it is advantageous that adhesive strength between the insulation film and the molding resin can be improved, and reliability and durability of the chip package (e.g. a COB type and the like) can be improved. Moreover, in spite of the use of polyimide as the insulating layer, the adhesive strength between the insulation film and the molding resin can be improved, and the heat resistance, mechanical properties, electrical characteristics, and flame resistance of a product based on the use of the polyimide can be also improved. Furthermore, as the chip package is manufactured using the flexible copper foil laminate film, the effects such as the light weight, small size, and simplified thin thickness of a product can be additionally achieved.

As previously described, in the detailed description of the invention, having described the detailed exemplary embodiments of the invention, it should be apparent that modifications and variations can be made by persons skilled without deviating from the spirit or scope of the invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims and their equivalents.

1. A chip package substrate, comprising:
a base substrate including via holes;
a circuit pattern layer formed in an area of the base substrate corresponding to the via holes; and
a first plated layer formed on the other surface opposite to a surface of the circuit pattern layer in contact with the via holes.

2-16. (canceled)

17. The chip package substrate of claim 1, further comprising a second plated layer formed on the surface of the circuit pattern layer in contact with the via holes.

18. The chip package substrate of claim 17, wherein the surface of the circuit pattern layer is a surface on a side of a bonding area to which chips are bonded.

19. The chip package substrate of claim 1, wherein the other surface of the circuit pattern layer is a surface on a side to which the circuit pattern layer is exposed.

20. The chip package substrate of claim 1, wherein the first plated layer comprises:
an Ni layer formed on the circuit pattern layer;
an alloy layer formed on the Ni layer; and
an Au layer formed on the alloy layer.

21. The chip package substrate of claim 17, wherein the second plated layer comprises:
an Ni layer formed on the circuit pattern layer;
an alloy layer formed on the Ni layer; and
an Au layer formed on the alloy layer.

22. The chip package substrate of claim 20, wherein the alloy layer is made of an alloy of Ni, P and B.

23. The chip package substrate of claim 20, wherein the alloy layer is formed in a thickness of 0.5±0.02 μm, and the Au layer is formed in a thickness of 0.05±0.02 μm.

24. The chip package substrate of claim 21, wherein the alloy layer is made of an alloy of Ni, P and B.

25. The chip package substrate of claim 21, wherein the alloy layer is formed in a thickness of 0.5±0.02 μm, and the Au layer is formed in a thickness of 0.05±0.02 μm.

26. The chip package substrate of claim 1, wherein the base substrate comprises:
an adhesive layer;
an insulating layer; and
a lower adhesive layer.

27. The chip package substrate of claim 26, wherein the insulating layer is made of polyimide, polyethylene naphthalate or polyethyleneterephthalate.

28. The chip package substrate of claim 26, wherein the lower adhesive layer is configured to bond the circuit pattern layer.

29. The chip package substrate of claim 26, wherein the lower adhesive layer is formed using an adhesive or a bonding sheet.

30. The chip package substrate of claim 26, wherein the adhesive layer has a roughness formed on its surface.
